(19) United States
(12) Patent Application Publication
(10) Pub. No.: US 2014/0195159 A1
(43) Pub. Date: Jul. 10, 2014

(54) APPLICATION OF ARTIFICIAL INTELLIGENCE TECHNIQUES AND STATISTICAL ENSEMBLING TO FORECAST POWER OUTPUT OF A WIND ENERGY FACILITY

(71) Applicant: ITERIS, INC., Santa Ana, CA (US)

(72) Inventors: JOHN J. MEWES, MAYVILLE, ND (US); LEON F. OSBORNE, GRAND FORKS, ND (US)

(21) Appl. No.: 14/150,784

(22) Filed: Jan. 9, 2014

Related U.S. Application Data
(60) Provisional application No. 61/750,481, filed on Jan. 9, 2013.

(51) Int. Cl. G01W 1/02; G01R 21/00

(52) U.S. Cl. CPC G01W 1/02; G01R 21/00
USPC 702/3

(57) ABSTRACT

A wind energy forecasting system processes data from one or more numerical weather prediction models with power output data from a wind energy facility using artificial intelligence. This artificial intelligence is applied in one or more neural networks that produce specific power output forecasts for each numerical weather prediction model. A statistical ensembling approach is then applied to the resulting numerical weather prediction model forecasts and integrated with a persistence power output forecast to arrive at a consensus, overall forecasted power output for the wind energy facility.

### CROSS-REFERENCE TO RELATED PATENT APPLICATIONS

This patent application claims priority to U.S. provisional application 61/750,481, filed on Jan. 9, 2013, the contents of which are incorporated in their entirety herein.

### FIELD OF THE INVENTION

The present invention generally relates to wind energy. Specifically, the present invention relates to an approach to modeling of weather data to forecast power output at a particular wind energy facility.

### BACKGROUND OF THE INVENTION

There are many existing methods of forecasting performance of a wind energy facility. Many such methods utilize weather data from numerical weather prediction models to predict weather conditions at a certain time and generate power output forecasts based on this weather data.

Some existing methods of modeling power output forecasts for wind energy facilities attempt to analyze details regarding the flow of air through a wind energy facility, and its interaction with each turbine to produce energy. This type of analysis uses an extremely high-resolution model to simulate the interaction of atmospheric flows with highly detailed local orography and the power facility's own wind turbines. Such a simulation utilizes a cumbersome conversion of meteorological forecast data into a forecast of power output. This yields a turbine-by-turbine wind forecast that can be applied to power curves to arrive at whole-facility energy output forecasts. While this concept has considerable scientific merit, the computational resources required to perform the power conversion in this manner limit the practicality of applying such a process. Further, applying this concept in concert with other concepts, such as ensemble modeling, is additionally cumbersome, as it requires repetition of this power conversion process for each member of the ensemble of numerical weather prediction models.

The use of computational resources also limits the ability of traditional forecasting methods to modulate weather data from numerical weather prediction models with actual power output data, whether such data is a reflection of historical power output or of current power output for the particular wind energy facility. Such integration of this historical and current power output information would be an advantageous improvement as it would substantially improve the accuracy of future power output forecasts based on the predictive weather data ingested in the numerical weather prediction models.

Existing methodologies using the techniques described lack the ability to draw analogies between specific pieces of weather data available in numerical weather prediction models and the corresponding power output capability of wind energy facilities. It is therefore an objective of the present invention to apply modeling techniques that attempt to analogize predictive weather information with power output. It is further an objective of the present invention to estimate power output at a wind energy facility based on similarities of a present situation with past situations in which power output is known. It is still a further objective of the present invention to apply ensembling concepts to the modeling techniques that attempt to analogize predictive weather information with persistence power output forecast data to improve accuracy and arrive at consensus power output forecasts for wind energy facilities.

### BRIEF SUMMARY OF THE INVENTION

The present invention accomplishes the objectives described above, and others, in a wind energy forecasting system and method operating such a system that processes atmospheric data variables from one or more numerical weather prediction models with a model of actual power output produced by a particular wind energy facility using artificial intelligence. This artificial intelligence is applied in one or more neural networks trained to analyze one or more numerical weather prediction (NWP) models, together with the actual power output model, and generate specific power output forecasts for each NWP model. The present invention then applies a statistical ensembling methodology to compare the resulting power output forecasts based on the NWP models, and further integrates a persistence power output energy forecast to arrive at a consensus forecast of power output for the wind energy facility.

Given adequate observational data, artificial intelligence techniques are applied so that the present invention quickly learns how each individual wind energy facility responds to various weather situations. Artificial intelligence in the form of neural networks eliminates steps in the traditional process of modeling meteorological data that introduce errors. The present invention takes the use of artificial intelligence further by incorporating neural networks trained by back-propagation techniques to draw non-linear relationships between raw and derived variables available in each NWP model and the corresponding whole-facility power output.

One or more objects of the present invention are further achieved by expanding upon the use of artificial intelligence through application of existing concepts of ensemble modeling and minimum variance estimation. The present invention therefore builds upon meteorological prediction data converted using artificial intelligence into power output forecasts by applying concepts of ensemble modeling and minimum variance estimation to arrive at consensus forecasts and improve overall forecast accuracy for power output at a wind energy facility.

The present invention contemplates delivery of power output forecasts generated from the wind energy forecasting system and method of the present invention in different formats that suit the specific needs of utilities and/or facility operators. For example, a data feed of power output forecasts may be delivered via e-mail, with forecast data arranged to meet custom requirements, such as for example in a tabular format with the columns and rows representing the hours of the day and the dates of the forecast, respectively. Multiple tables containing hourly forecasts for the current day and a following number of hours and/or days may also be provided. Forecast data may also be delivered via spreadsheets or other formats that can be utilized by specific end-user systems for managing, viewing, and manipulating the forecast data. Forecast data may be further delivered via a wired or wireless data transmission feed, and such a delivery may further occur with a secure, distributed computing environment. Regardless of the delivery paradigm utilized, it is to be understood that delivery of forecast may be in any form required by the wind energy facility to be modeled.

The present invention may further include a user interface, which may graphically display visualized and/or animated power output forecast data for operators of wind energy facilities. One or more software modules that perform the various data modeling functions described herein may be incorporated in a utility program configured to carry out the power output forecasting objectives of the present invention. The user interface capability is further provided by one or more graphical user interface modules configured to permit visual and/or animated manipulations of data to be modeled as well as the resulting power output forecast data by users responsible for wind energy facility operations.

Other embodiments, features and advantages of the present invention will become apparent from the following description of the embodiments, taken together with the accompanying drawings, which illustrate, by way of example, the principles of the invention.

### BRIEF DESCRIPTION OF THE SEVERAL VIEWS OF THE DRAWINGS

The accompanying drawings, which are incorporated in and constitute a part of this specification, illustrate several embodiments of the invention and together with the description, serve to explain the principles of the invention.

FIG. 1 is a systemic diagram showing a wind energy power output forecasting system according to the present invention; and

FIG. 2 is a diagram showing components for modeling of weather input variables and ensembling of specific NWP model forecasts in a wind energy power output forecasting system according to the present invention.

### DETAILED DESCRIPTION OF THE INVENTION

In the following description of the present invention reference is made to the accompanying figures which form a part thereof, and in which is shown, by way of illustration, exemplary embodiments illustrating the principles of the present invention and how it is practiced. Other embodiments will be utilized to practice the present invention and structural and functional changes will be made thereto without departing from the scope of the present invention.

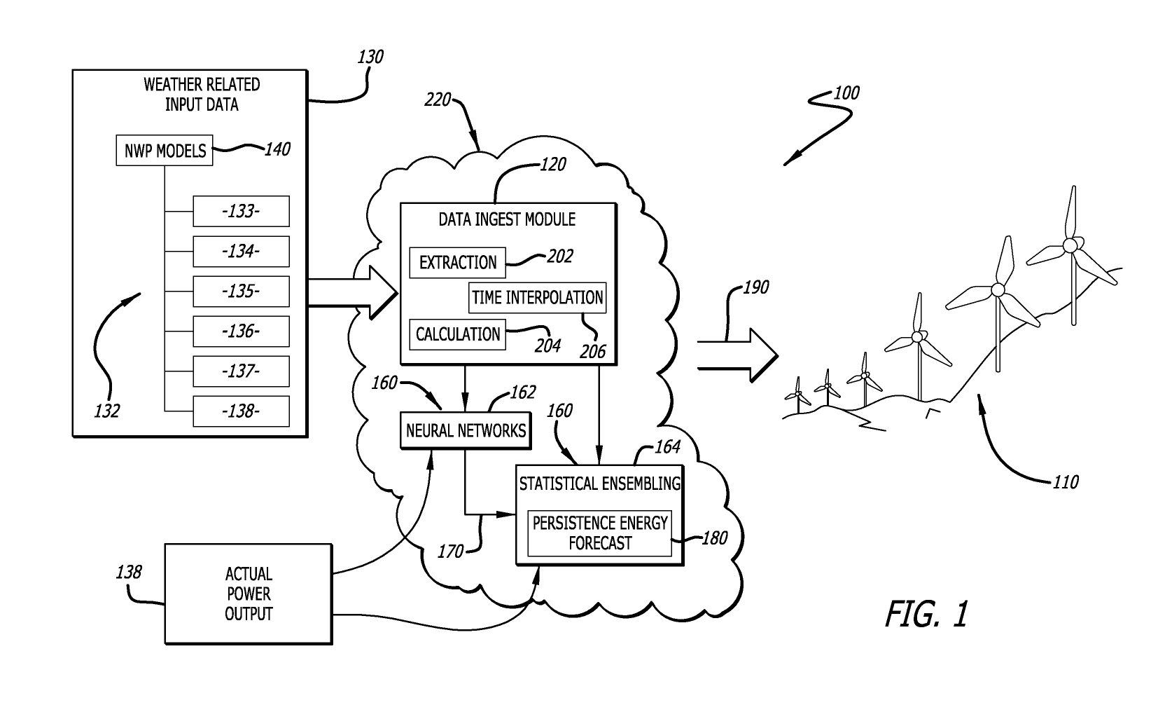

FIG. 1 is a diagram of a wind energy forecasting system 100 for a wind energy facility 110. The wind energy forecasting system 100 includes a data ingest module 120 that accepts a plurality of input data 130 from many different sources. The plurality of input data 130 includes one or more weather variables 132 from numerical weather prediction (NWP) models 140. These one or more weather variables collectively represent meteorological forecasts 150 for the area in which the wind energy facility 110 is located. A plurality of data processing modules 160 model this input data 110, in one or more neural networks 162 and by applying a statistical ensembling approach in a module 164. Actual power output data in the form of an actual amount of energy produced 138, and a persistence power output energy forecast 180, are further applied to the data processing modules 160, as discussed herein, to generate a forecast of energy to be produced by the wind energy facility 110 in a consensus power output forecast 190. The wind energy forecasting system 100 operates within a computing environment 220 that includes one or more processors in a plurality of software and hardware components configured to execute program instructions to perform functions described herein.

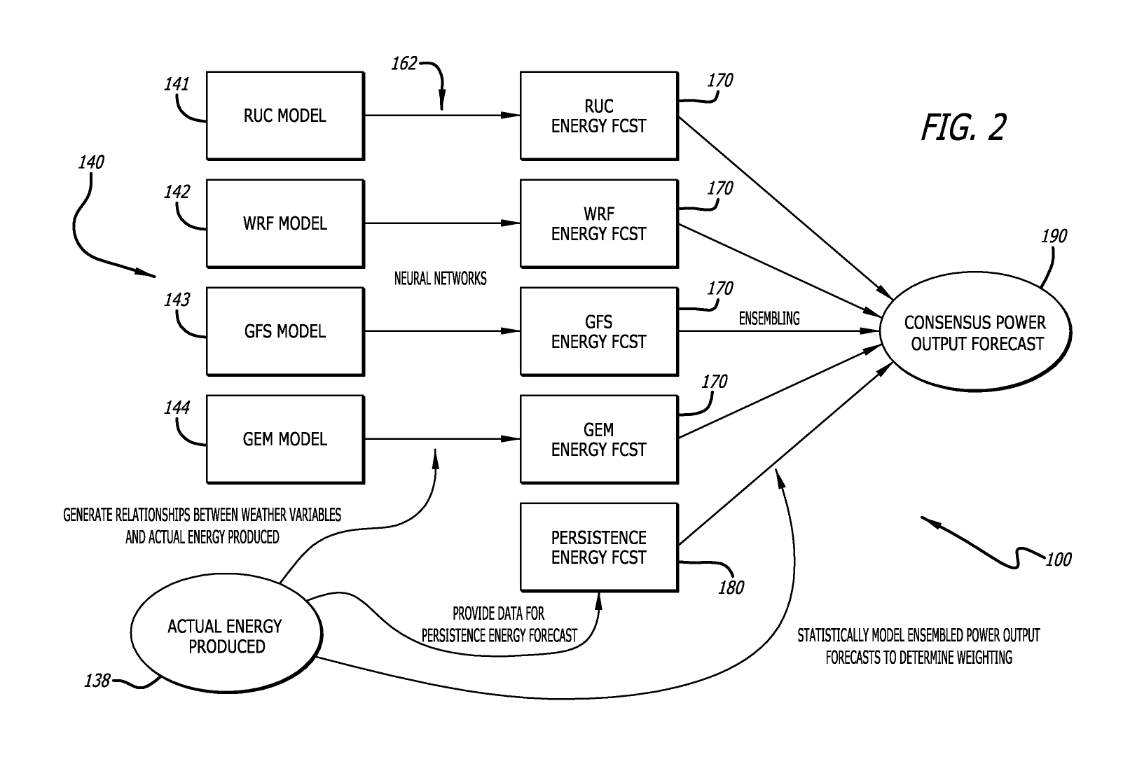

FIG. 2 is another diagram of a wind energy forecasting system 100 according to one embodiment of the present invention. The wind energy forecasting system 100 includes, as noted above, a data ingest module 120 that accepts the plurality of input data 130 from many different sources. The plurality of input data 130 includes data representative of weather variables 132 that are run from numerical weather prediction (NWP) models 140. There are numerous industry NWP models 140 available, and any such models may be used to input weather variables in the present invention. NWP models 140 used herein at least include RUC (Rapid Update Cycle) 141, WRF (Weather Research and Forecasting Model) 142, GFS (Global Forecast System) 143, and GEM (Global Environmental Model) 144. This weather-related input data 130 is received in real-time, and may come from several different NWP sources, such as from Meteorological Services of Canada (MSC) and the Canadian Meteorological Centre (CMC), as well as the National Oceanic and Atmospheric Administration's (NOAA) Environmental Modeling Center (EMC), and many others. It is to be noted that the models 140 shown in FIG. 2 are exemplary, and as indicated above, any of a number of different models may be utilized for weather variables 132 in the present invention. Accordingly, the present invention is not to be limited by the use of any particular NWP model 140 or group of models 140.

Regardless of the specific model or source, it is to be understood that different model 140 runs provide predicted weather variables 132 in input data 130 for the present invention, and that these different models 140 and predicted weather variables 132 are used by the present invention to provide tightly-integrated and accurate power output forecasting for a wind energy facility 110. Data ingest processes are continuously monitored, and automatically trigger immediate processing of weather variables 132 from these prediction models 140 at the time of ingest. Predicted weather variables 132 are therefore continuously blended into the wind energy power output forecasting of the system 100.

The input data 130 also includes actual power output data in an actual amount of energy produced 138 at the wind energy facility 110. Data representative of weather variables 132 is ingested into one or more neural networks 162, which are trained to analyze relationships between the weather variables 132 provided in the NWP model 140 runs and the actual amount of energy produced 138 over a specific period of time at a wind energy facility 110 at which the power output is to be forecasted. The actual amount of energy produced 138 therefore acts as a training data set for the neural networks 162, which are configured to analyze actual energy production over a period of time and for conditions similar to those represented by the weather variables 132 in the runs of NWP models 140. In this manner, the neural networks 162 are configured to understand what a modeled power output forecast should resemble in light of weather variables 132 in the NWP models 140.

The one or more neural networks 162 also generate power output forecasts 170 of energy to be produced for each NWP model 140 based on the analyzed relationships between the weather variables 132 included in the NWP models 140 and the actual amount of energy produced 138 over a specific period of time at a wind energy facility 110. After generation of these power output forecasts 170 for each NWP model 140, the present invention contemplates that data representative of the real-time, current power output of the wind energy facility 110 may also be fed back into the wind energy forecasting system 100 in a persistence power output energy forecast 180. Such a persistence power output energy forecast 180 allows the wind energy forecasting system 100 to assume a persistence of this same power output, and to consider this data as a component of neural network-modeled weather data in further modeling phases to be described below.

The power output forecasts 170 generated by the neural networks 162 for each NWP model 140, together with the persistence power output energy forecast 180, are then applied in a statistical ensembling approach in module 164 that generates a consensus power output forecast 190 for the period of time represented in the weather variables 132 in the NWP models 140. The statistical ensembling module 164 provides an approach to further modeling of power output forecast data 170 from the neural networks 162, in which the present invention continuously updates a statistical analysis of each neural network-modeled power output forecast 170 for each NWP model 140 as a comparison with the real-time energy produced by the wind energy facility 110 to increase the accuracy of the overall consensus power output forecast 190. This is performed by weighting each power output forecast 170 for an individual NWP model 140 to arrive at a minimum variance estimate. The consensus power output forecast 190 for the period of time generated by the wind energy forecasting system 100 is therefore a weighted estimate of the power output of the wind energy facility 110 based on degrees of similarity of present conditions to past conditions where a power output of the wind energy facility 110 is already known.

The statistical ensembling approach in the module 164 helps maintain forecast performance accuracy of the individual weather prediction models 140 as a function of a power output forecast's lead time. This is realized when considered in light of the time period over which power output forecasts 170 are provided—when the present invention generates a near-time (for example, +1 hour) wind energy forecast, it might draw heavily from the persistence power output energy forecast 180. However, with a longer time frame (for example, +10 hour), the power output forecast 170 will rely more heavily on forecasts developed from weather variables 132 in numerical weather prediction model data 130. It is therefore understood that this statistical ensembling approach is a method of modulating power output forecasts as a function of the time period over which they are to be provided.

Ensemble modeling in the module 164 is a process involving the blending of data from NWP models 140 to arrive at both a consensus power output forecast 190 as well as an estimation of the amount of uncertainty in that consensus power output forecast 190. The theory of minimum variance estimation is used in this ensemble modeling approach 164 to combine the power output forecasts 170 from the NWP models 140 comprising the ensemble members in a manner that mathematically guarantees a lower consensus error variance than any one of the power output forecasts 170 from individual NWP models 140 can provide individually. The present invention applies the concepts of ensemble modeling and minimum error variance to data modeled by artificial intelligence, in the form of neural networks 162, to draw direct relationships between weather variables 132 in NWP models 140 and power output or other observations from an existing wind energy facility 110.

It is to be understood that the present invention may generate a consensus power output forecast 190 for a wind energy facility 110 by modeling a plurality of different weather variables 132 ingested from runs of different NWP models 140. Different NWP models 140 and groups of models 140 may be utilized at different times, since not all models 140 communicate weather forecasts at the same time, and with the same variables 132.

Additionally, internally or privately-generated “mesoscale” NWP models 146 developed from data collected from real-time feeds to global observation resources may also be utilized. Such mesoscale numerical weather prediction models 146 may be specialized in forecasting weather with more local detail than those models operated at government centers, and therefore contain smaller-scale data collections than other NWP models 140 used. These mesoscale models 146 are very useful in characterizing how weather conditions may vary over small distances. The data ingest module 120 of the present invention may be configured to monitor ingest processes for data 130 from runs of all types of NWP models 140, regardless of whether publicly, privately, or internally provided or developed, and to automatically trigger immediate processing of data 130 from any of these models 140 upon arrival.

The data ingest module 120 also performs several processing functions 200 on input data 130, at least to discern weather variables 132 from the streams of data from NWP models 140. These processing functions 200 at least include extraction 202 of atmospheric profile data 133 for the location of a wind energy facility 110 from gridded NWP data, calculation 204 of derived parameters 134 from that atmospheric profile data 133 (e.g., parameters such as expected wind gust speeds), and the time interpolation 206 of the atmospheric profile 133 into a common framework time for modeling by the wind energy forecasting system 100. The arrival of a new atmospheric profile 133 from any single NWP model 140 for a given time and location triggers all subsequent processing (i.e., the subsequent power conversion and ensembling processes are data-driven). The resulting power output forecast 170 generated from neural networks 162 for different forecast hours therefore updates asynchronously and at frequencies that depend upon how often input data 130 is ingested for its associated lead time.

As noted above, after input data 130 is ingested into the present invention, weather variables 132 in the atmospheric profile 133 that are expected to have some relationship to the power produced by a particular wind energy facility 110 whose power output is to be forecasted are identified and extracted for processing in the one or more neural networks 162. Other examples of these weather variables 132 in the atmospheric profile 133 to be extracted include a vertical profile 135 of expected wind speed and wind direction characteristics, temperature, humidity, stability, turbulent transfer, and precipitation at the location of the wind energy facility 110. Where the wind energy facility 110 is a located over a large geographical area, it may be possible to isolate data from the gridded NWP data for turbines located at different elevations or in different zones of the wind energy facility 110. Regardless, the present invention is configured to analyze weather variables 132 run from the NWP models 140 that have a substantive relationship to the power output. All other weather variables 132 are discarded from the input data 110 provided to the one or more neural networks 162 for processing.

The historical power output, or actual amount of energy produced 138, of the wind energy facility 110 for the same period of time as the power output to be modeled for those weather conditions is then applied to train the one or more neural networks 162 to predict the desired power output forecast 170 from the weather variables 132 of the NWP models 140. In one embodiment, the present invention utilizes a back-propagation technique to train a neural network 162 to produce a specific power output forecast 170 from the weather variables 132 in the NWP models 140. The back-propagation technique heuristically builds the neural network 162 from the input data sets provided by the NWP models 140 and the actual amount of energy produced 138. This allows the trained neural networks 162 to be applied to incoming data sets as in the present invention where weather variables 132 are known, and a forecasted power output 170 is sought. It is to be understood that training of neural networks 162 to heuristically build the ability to generate desired power output forecasts 170 may occur repetitively in the present invention, so that the one or more neural networks 162 are continually updated to provide accurate forecasts 170. Such a repetitive training approach helps to account for seasonal changes in weather and also to properly account for the effects of unusually severe or mild weather conditions at any given time at the location of the wind energy facility 110.

Numerical weather prediction (NWP) models 140 offer different weather data based largely on the time frame within which weather events are expected. In the present invention, the one or more neural networks 162 are configured to analyze each NWP model 140 and generate a power output forecast 170 for each set of input data 130 containing weather variables 132. Since these power output forecasts 170 are later ensembled, the present invention is able to account for time differences in the numerical weather prediction models 140 and integrate transient weather events into the power output forecasts 170.

For weather events occurring within one hour in an incoming data set representative of such a “nowcast” NWP model 140, the present invention utilizes a combination of short-duration NWP model runs and a special persistence forecasting technique. Real-time weather observations are routinely analyzed and used to initialize NWP models 140, the power output forecasts 170 from which are then fed into the present invention and blended into statistical ensembling. The present invention therefore has the ability to predict the response of a wind energy facility 110 to transient weather events. However, over this very short time frame current power output can often be the best predictor of near-term power output. As such, a pattern recognition system is applied, which looks at the recent time-series of power output from the wind energy facility 110 and generates a special persistence power output energy forecast 180 that is based upon how power output from the wind energy facility 110 has typically behaved after similar patterns of power output in the past. This persistence power output energy forecast 180 is created immediately upon receipt of a new power output observation from the wind energy facility 110, and is integrated into the ensembling module 164 immediately after generation. Thus, within minutes of receipt of new observational data from the wind energy facility 110, the present invention is able to update its short-term forecast to reflect current trends.

Numerical weather prediction models 140 begin to exhibit more skill than persistence-based predictive techniques at somewhere between 2 and 4 hours of lead time. At a lead time of +2 hours the weighting between ensemble members arrived at using the two techniques tends to be nearly equal. While ensemble members created using both NWP models 140 and persistence techniques are still included in the overall ensemble-based power output forecast out to +6 hours, the weighting assigned to the persistence-based ensemble members falls dramatically with each additional hour of lead time so that the ensemble-averaged forecasts with 6-hour or greater lead time tend to be almost entirely made up of NWP-based ensemble members.

Beyond a 6-hour lead time, the present invention may increasingly rely on power output forecasts 170 created using the artificial intelligence techniques in the one or more neural networks 162 on predictors drawn from NWP models 140. Beyond 6 hours, therefore, a large number of ensemble members used to create the ensemble-averaged (consensus) power output forecast significantly increases the accuracy. Also, the application of a large number of power output forecasts 140 from NWP models 140 provides the ability to distinguish which transient weather events are likely to occur and which are not.

Multiple neural networks 162 may be applied for a particular NWP model 140, each using a different network structure as well as a different set of weather predictors drawn out of the NWP model data, and therefore, each may be separately trained in a manner specific to the data contained in the NWP model 140. When the resulting forecast data for each NWP model 140 is ensembled, the heuristic modeling approach can further tune the power output forecast 170 for the particular wind energy facility 110 by data generated from separately trained artificial intelligence.

It is to be noted that weather variables 132 are not, in general, required or expected to be turbine-level, readily-observable parameters. They are merely predictors that describe any one of a number of aspects of the simulated lower atmosphere in the NWP model 140 that might be expected to have some predictable relationship to the power output of the wind energy facility 110. As such, creation of a turbine-level meteorological forecast 210 is generally not included within a consensus power output forecast 190 for the wind energy facility 110. Since the relationships between weather variables 132 and wind energy facility power output are drawn directly by artificial intelligence techniques embodied in the one or more neural networks 162, a meteorological forecast 210 for the wind energy facility 110 is not a separable component of the consensus power output forecast 190. However, in one embodiment of the present invention, artificial intelligence in the form of a specific or dedicated neural network 162 may be trained to identify a meteorological forecast 210 for the time period over which the consensus power output forecast 190 is to be generated, so that this information can be made separable for analysis prior to drawing such relationships. Such a meteorological forecast 210 may then be separately generated as a separate output of a neural network 162 that is not statistically ensembled with the power output forecast 170 for each NWP model 140, as a separate set of output data alongside the consensus power output forecast 190. In this embodiment, the output provided for the operator of the wind energy facility 110 may receive two sets of data—the consensus power output forecast 190, and a turbine-level meteorological forecast 210, for a defined period of time. The turbine-level meteorological forecast 210 may then be used to enable further analysis over time of the consensus power output forecast 190, and improve its real-time accuracy, by providing an understanding of how power output may change in light of the forecasted weather conditions at the wind energy facility 110.

As noted herein, the present invention includes a persistence power output energy forecast 180 as an input that is ensembled with the power output forecasts 170 processed by the one or more neural networks 162. The persistence power output energy forecast 180 is representative of the real-time power output of the wind energy facility 110 and is generated by examining recent (i.e., within hours) wind energy facility power output under similar patterns of power output over a preceding time period. In one aspect, artificial intelligence techniques embodied in the one or more neural networks 162 are also utilized to project the power output going forward based upon similarities of a current power output profile to behavior of the wind energy facility 110 in similar situations in the past. This results in a persistence power output energy forecast 180, which adds value primarily in lead time ranges of a few hours. This persistence power output energy forecast 180 is then modeled in the same manner as the NWP-based power output forecasts 170 by the statistical ensembling approach 164 using minimum variance estimation.

The present invention employs statistical ensembling techniques in module 164 to further model power output forecasts 170 for a wind energy facility based on weather variables 132 in NWP models 140 because, at time frames in excess of a few hours, uncertainties in those NWP model-based power output forecasts 170 increase the percentage chances of inaccuracies. For example, correctly timing the extrema in power output is of critical importance in administering the use of wind energy resources. Reliance upon a single NWP model 140 leaves the user of the resultant consensus power forecast 190 highly susceptible to timing errors in that model.

Statistically combining an “ensemble” of NWP model-based power output forecasts 170 to arrive at a consensus power output forecast 190 that exhibits more robust timing predictions alleviates the problem of timing errors, and may also provide an indicator of forecast uncertainty over time. Members of the statistical ensemble may be made up of any or all of the following: different NWP models 140, different physical or dynamical schemes within each NWP model 140, or different lead times for a given NWP model 140. The broad range of inputs producing the power output forecasts 170 for NWP ensemble members acts as a powerful filter for distinguishing likely events from outliers in an individual NWP model 140 and potentially for providing some measure of the relative uncertainty in a consensus power output forecast 190, by analyzing the similarity between power output forecasts 170 created by each NWP ensemble member. Likewise, the use of an ensemble of NWP-based power output forecasts 170 also reduces susceptibility to the day-in, day-out shortcomings of any one particular model 140.

As noted above, one methodology for combining power output forecasts 170 for each of the NWP ensemble members to arrive at a consensus power output forecast 190 is the mathematical theory of minimum variance estimation. The general premise behind minimum variance estimation is that the addition of information from each new source of forecast data will improve a consensus power output forecast 190 as long as those forecasts are unbiased and weighted correctly. Minimum variance estimation provides that the combined forecast will be more accurate than that from any of the contributing models 140, taken individually. To apply this concept, the present invention updates and maintains records of the recent and historical performance for each neural network-modeled NWP model 140 at the wind energy facility 110, as measured against observations from that wind energy facility 110.

The present invention also tracks the performance of persistence and climatology forecasts at the wind energy facility 110. These NWP, persistence, and climatology forecast performance statistics are used when calculating the appropriate corrections and weights to apply in the minimum variance estimation step in order to guarantee a statistically-superior ensembled output. The corrections and weights assigned to each of these forecast sources are therefore able to adapt to the recent performance of each ensemble member over time, allowing the creation of an ensemble forecast that is statistically tuned to recent performance.

As indicated above, the present invention may also track climatology forecasts at the wind energy facility 110 over a period of time and incorporate this historical data into the statistical ensembling approach 164 to arrive at a consensus power output forecast 190. Adding such historical climatology data further enhances the accuracy of the consensus power output forecast 190 by permitting ensembled comparisons of an additional set of data together with the power output forecast 170 for each NWP model 140 and the persistence power output energy forecast 180.

The present invention may therefore incorporate climatology of a wind energy facility 110 for energy production, such as the average hourly production for a particular period of time. The present invention may apply particular mathematical modeling, such as a Fast Fourier, to these average values to identify trends in the data with the objective of identifying long-term trends for application to the statistical ensembling approach. Fourier analysis, which is a type of harmonic analysis, is a mathematical tool used for analyzing periodic functions by decomposing functions into a weighted sum of much simpler sinusoidal component functions, and a Fast Fourier analysis refers to a specific algorithm for performing the Fourier analysis. The analysis attempts to identify cycles, or trends, in the data, which may be combined together to provide a single equation to be used to generate a climatology of hourly energy production values for the wind energy facility 110. These cycles or trends help to explain the variability in energy production over the specific period of time, and therefore it is possible that some cycles will be classified according to quality. It is to be noted therefore that some cycles and trends may be removed from combination in the single equation used to generate the climatology data for historical energy production for the wind energy facility 110 to be modeled.

The systems and methods of the present invention described herein may be implemented in many different computing environments. For example, they may be implemented in conjunction with a special purpose computer, a programmed microprocessor or microcontroller and peripheral integrated circuit element(s), an ASIC or other integrated circuit, a digital signal processor, electronic or logic circuitry such as discrete element circuit, a programmable logic device or gate array such as a PLD, PLA, FPGA, PAL, and any comparable means. In general, any means of implementing the methodology illustrated herein can be used to implement the various aspects of this invention. Exemplary hardware that can be used for the present invention includes computers, handheld devices, telephones (e.g., cellular, Internet enabled, digital, analog, hybrids, and others), and other such hardware. Some of these devices include processors (e.g., a single or multiple microprocessors), memory, nonvolatile storage, input devices, and output devices. Furthermore, alternative software implementations including, but not limited to, distributed processing, parallel processing, or virtual machine processing can also be configured to perform the methods described herein.

The systems and methods of the present invention may also be partially implemented in software that can be stored on a storage medium, executed on programmed general-purpose computer with the cooperation of a controller and memory, a special purpose computer, a microprocessor, or the like. In these instances, the systems and methods of this invention can be implemented as a program embedded on personal computer such as an applet, JAVA® or CGI script, as a resource residing on a server or computer workstation, as a routine embedded in a dedicated measurement system, system component, or the like. The system can also be implemented by physically incorporating the system and/or method into a software and/or hardware system.

Additionally, the data processing functions disclosed herein may be performed by one or more program instructions stored in or executed by such memory, and further may be performed by one or more modules configured to carry out those program instructions. Modules are intended to refer to any known or later developed hardware, software, firmware, artificial intelligence, fuzzy logic, expert system or combination of hardware and software that is capable of performing the data processing functionality described herein.

It is to be understood that other embodiments will be utilized and structural and functional changes will be made without departing from the scope of the present invention. The foregoing descriptions of embodiments of the present invention have been presented for the purposes of illustration and description. It is not intended to be exhaustive or to limit the invention to the precise forms disclosed. Accordingly, many modifications and variations are possible in light of the above teachings. It is therefore intended that the scope of the invention be limited not by this detailed description.

1. A method of forecasting power output of a wind energy facility, comprising:
ingesting one or more data sets representative of meteorological forecasts for an area in which a wind energy facility is located from at least one of multiple numerical predictive weather models;
extracting weather variables from the one or more data sets having an expected relationship to a power output production generated by the wind energy facility;
ingesting an actual power output data that is representative of historical power output of the wind energy facility for a specified period of time;
applying, within a computing environment comprised of at least one computer processor configured to model a specific power output forecast for a wind energy facility within a plurality of data processing modules, the weather variables and the actual power output data to heuristically build one or more neural networks to infer non-linear relationships between the weather variables and the actual power output data of the wind energy facility to produce a specific power output forecast for each numerical weather prediction model;
projecting a current time-series representation of power output of the wind energy facility to create a persistence power output forecast; and
creating an ensemble average consensus power output forecast for the specified period of time from numerical weather prediction models and persistence power output forecast comprising ensemble members, each ensemble member having a weight determined by recent and real-time statistical assessments of an accuracy of each specific power output forecast for the wind energy facility.

2. The method of claim 1, wherein the applying the weather variables and the actual power output data to one or more neural networks further comprises heuristically building multiple neural networks for a given numerical weather prediction model, each neural network using a different network structure and a different set of predictors drawn out of the weather variables.

3. The method of claim 1, further comprising repetitively training the one or more neural networks to continuously update the specific power output forecasts from the numerical weather prediction models to account for seasonal changes in weather and for the effects of unusually severe and unusually mild weather conditions at the location of the wind energy facility.

4. The method of claim 1, wherein the creating an ensemble average consensus power output forecast further comprises applying a minimum variance estimation to improve overall forecast accuracy.

5. The method of claim 1, wherein the creating an ensemble average consensus power output forecast further comprises weighting each power output forecast, for an individual numerical weather prediction model and/or a persistence power output forecast, to produce a minimum variance estimate.

6. The method of claim 5, wherein the weighting each power output forecast for an individual numerical weather prediction model and/or persistence power output forecast to arrive at a minimum variance estimate further comprises assigning a weighted estimate based on degrees of similarity of present conditions to past conditions where the actual power output data of the wind energy facility is already known.

7. The method of claim 1, further comprising determining a specified period of time over which the ensemble average consensus power output forecast for the wind energy facility is generated, wherein the specified period of time determines a time-dependent weighting applied to each specific numerical weather prediction model and/or persistence power output forecast.

8. The method of claim 1, wherein the weather variables define an atmospheric profile that at least includes at least one of a vertical profile of expected wind speed and wind direction characteristics, temperature, humidity, stability, turbulent transfer, and precipitation, at the location of the wind energy facility.

9. The method of claim 1, wherein the ensemble average consensus power output forecast comprises at least one of: a set of one or more different numerical weather prediction models, a set of one or more different physical or dynamical schemes within each numerical weather prediction model, and a set of one or more different lead times for a specific numerical weather prediction model.

10. The method of claim 1, further comprising applying, to the ensemble of numerical weather prediction models and persistence power output forecast from which the specific power output forecasts are produced, historical climatology data representing average power output production for a time interval, and further comprising applying a Fast Fourier analysis to the average power output production to identify long-term cycles in the historical climatology data that explain variability in power output over the specified period of time.

11. The method of claim 1, wherein the persistence power output forecast are generated by comparing a power output of the wind energy facility for a particular time interval and with power output over preceding, similar time intervals.

12. The method of claim 1, further comprising enabling graphical displays of power output forecast data for operators of wind energy facilities on a graphical user interface, the graphical displays providing one or more of visualizations and animations of the consensus power output forecast.

13. A wind energy forecasting system, comprising:
at least one computer processor operably coupled to at least one computer-readable storage medium having program instructions stored therein, the at least one computer processor configured to execute the program instructions to model weather variables representative of one or more meteorological conditions and generate specific power output forecasts for a wind energy facility in a plurality of data processing modules, the plurality of data processing modules including:
an input data collection module configured to continually ingest weather data comprising the weather variables from one or more numerical weather prediction model runs, an actual power output data collection module configured to ingest data relative to a real-time and historical power output of the wind energy facility over a specified period of time;
a plurality of neural networks heuristically built from the weather variables from the input data collection module and the historical power output from the actual power output data collection module, and trained to infer non-linear relationships between the weather variables and the historical power output of the wind energy facility to produce a specific power output forecast for each numerical weather prediction model for the meteorological conditions represented in the weather variables;
an ensembling module configured to aggregate the specific power output forecasts from each numerical weather prediction model run, and a persistence power output forecast based on real-time power output, into an ensemble of members by continuously tracking statistical properties of each specific power output forecast to assign a weight for each specific power output forecast, the weight determined based on a minimum variance estimation; and
a power production module configured to generate output data representative of a consensus power output forecast for the wind energy facility.

14. The system of claim 13, wherein the plurality of neural networks further comprises multiple neural networks for a given numerical weather prediction model, and each neural network for a given numerical weather prediction model uses a different network structure and a different set of predictors drawn out of the weather variables.

15. The system of claim 13, wherein the plurality of neural networks are repetitively training to continuously update the specific power output forecasts from the numerical weather prediction models to account for seasonal changes in weather and for the effects of unusually severe and unusually mild weather conditions at the location of the wind energy facility.

16. The system of claim 13, wherein the weather variables define an atmospheric profile that at least includes a vertical profile of expected wind speed and wind direction characteristics, temperature, humidity, stability, turbulent transfer, and precipitation, at the location of the wind energy facility.

17. The system of claim 13, wherein the ensemble of members comprises at least one of: a set of different numerical weather prediction models, a set of different physical or dynamical schemes within each numerical weather prediction model, and different lead times for a specific numerical weather prediction model.

18. The system of claim 13, wherein the persistence power output forecasts are generated by comparing a power output of the wind energy facility for a particular time interval and with power output over preceding, similar time intervals.

19. The system of claim 13, further comprising a graphics module configured to generate one or more of visualizations and animations of the output data display on a graphical user interface for operators of wind energy facilities.

20. A method of forecasting power output of a wind energy facility, comprising:
modeling weather variables from a plurality of numerical weather prediction models and actual power output data of wind energy facility, by:
heuristically building one or more neural networks by training each neural network to infer non-linear relationships between the weather variables and the actual power output data of wind energy facility to produce a specific power output forecast for each numerical weather prediction model for the meteorological conditions represented in the weather variables;
aggregating the numerical weather prediction models from which the specific power output forecasts are produced into an ensemble of numerical weather prediction model members; and
statistically combining the specific power output forecast for each numerical weather predictive model with a real-time persistence power output forecast of the wind energy facility by assigning a weight to each specific power output forecast to produce a minimum variance estimate.

21. The method of claim 20, wherein the heuristically building one or more neural networks further comprises heuristically building multiple neural networks for a given numerical weather prediction model, each neural network using a different network structure and a different set of predictors drawn out of the weather variables.

22. The method of claim 20, further comprising repetitively training the one or more neural networks to continuously update the specific power output forecasts from the numerical weather prediction models to account for seasonal changes in weather and for the effects of unusually severe and unusually mild weather conditions at the location of the wind energy facility.

23. The method of claim 20, further comprising determining a specified period of time over which a consensus power output forecast for the wind energy facility is generated, wherein the specified period of time determines a time-dependent weighting applied to each specific numerical weather prediction model and persistence power output forecast.

24. The method of claim 20, further comprising generating one or more of visualizations and animations of the output data display on a graphical user interface for operators of wind energy facilities.

25. The method of claim 20, wherein the weather variables define an atmospheric profile that at least includes a vertical profile of expected wind speed and wind direction characteristics, temperature, humidity, stability, turbulent transfer, and precipitation, at the location of the wind energy facility.
